(19) United States
(12) Patent Application Publication
(10) Pub. No.: US 2002/0180430 A1
(43) Pub. Date: Dec. 5, 2002

(54) Fixture for plate type magnetic resistance sensor chip element

(75) Inventor: Eung-Cheon Kang, Suwon (KR)

Correspondence Address: LOWE HAUPTMAN GOPSTEIN GILMAN & BERNER, LLP, Suite 310, 1700 Diagonal Road, Alexandria, VA, 22314, US

(73) Assignee: SAMSUNG ELECTRO-MECHANICS CO. LTD.

(21) Appl. No.: 09/957,614

(22) Filed: Sep. 21, 2001

(30) Foreign Application Priority Data
Jun. 1, 2001 (KR) 2001-30746

(51) Int. Cl. G01R 33/02

(52) U.S. Cl. 324/252; 324/262

(57) ABSTRACT

Disclosed is a fixture for a magnetic resistance sensor chip. A rectangular magnetic resistance sensor chip having a sensing part on one side thereof and an electrode at every corner on both sides thereof is fixed onto a front side of a PCB which has a pattern part on the front side, such that the electrode is in contact with the pattern part. The PCB is provided with a through-hole coated with a conductor connected to a terminal part formed on its back side. The PCB associated fixedly with the magnetic resistance sensor chip is installed onto a motor board with a magnet mounted. The installation is achieved by soldering the back side terminal part onto the motor board. Facing the magnet, the sensing part is located at a predetermined distance from the magnet. In the fixture, the magnetic resistance sensor chip can be fixed to a PCB without requiring an additional holder and mounted onto a board of a motor with ease. Resulting from the novel structure of the plate type magnetic resistance sensor chip on both sides of which electrode patterns are formed, no interference between the magnet and the magnetic resistance sensor chip occurs upon mounting.

### BACKGROUND OF THE INVENTION

1. Field of the Invention

The present invention relates to a fixture for plate-type magnetic resistance (hereinafter referred to as “MR”) sensor chip elements, which are used for controlling rotational speeds of capstan motors for use in VCR, camcoders, and the like. More particularly, the present invention relates to a fixture which requires no additional holders in fixing and mounting plate-type MR sensor chips on a printed circuit board (PCB) and a motor board and allows the simplification of the fabricating and mounting processes of an MR sensor chip.

2. Description of the Prior Art

In order to better understand the background of the invention, a description will be given of a conventional fixture for MR sensor chips in conjunction with accompanying drawings. FIG. 1 shows a conventional MR sensor chip 20 engaged via an adhesive to a chip holder 10 made of an insert injection. In this structure, a lead frame 30 is connected to an electrode 21 of the MR sensor chip by a solder 40 and this connection is coated with an insulating epoxy resin 50.

The conventional MR sensor chip 20 engaged to the chip holder, as shown in FIG. 2, is mounted at one side of a magnet 70 on a motor board 60 in such a way that the MR sensor chip 20 stands facing the magnet 70 to control the rotational speed of the motor.

As disclosed in the above description, the fabrication of the conventional MR sensor chip requires complex processes, including insert injection for molding the chip holder 10 for fixing the MR sensor chip 20, soldering for connecting the lead frame 30 to the electrode 21 of the MR sensor chip 20, and application of the epoxy resin 50 to insulate the soldering portion.

Particularly by applying the epoxy resin 50 to the solder 40, the connection between the lead frame 30 and the electrode 21 on a sensing face of the MR sensor chip 20, the electrode 21 protrudes from the surface of the MR sensor chip 20. To protectively insulate the projection, an epoxy resin 50 is required to be applied on the soldering 40, but this treatment makes the electrode 21 more prominent. When the MR sensor chip 20 fixed to the chip holder 10 is mounted onto the motor board 60, there occurs interference between the magnet, serving as a rotor, and the projection of the epoxy resin coated on the electrode 21. To avoid the interference, the magnet 70 is installed, being space from the board at the distance as long as the thickness (t) of the epoxy resin 50. Hence, the structure of the conventional MR sensor chip makes the fabrication process difficult.

### SUMMARY OF THE INVENTION

Therefore, it is an object of the present invention to overcome the above problems encountered in prior arts and to provide a fixture which can easily and simply fix on a PCB and mount on a motor board an MR sensor, without the aid of additional holders.

It is another object of the present invention to provide a fixture which allows the simplification of the fabricating and mounting processes of an MR sensor chip.

It is a further object of the present invention to provide a fixture which can install an MR sensor chip on a board with a magnet mounted thereon, without interference between the MR sensor chip and the magnet.

It is still a further object of the present invention to provide a fixture which allows the magnet to be mounted without requiring a space to the board.

In accordance with an aspect of the present invention, there is provided a fixture for a magnetic resistance sensor chip, comprising: a rectangular magnetic resistance sensor chip having a sensing part 20 on one side thereof and an electrode at every corner on both sides thereof; a printed circuit board having a pattern part on its front side, a through-hole coated with a conductor, and a terminal part on its back side, said conductor being connected to the pattern part on the front side and to the terminal part on the back side; and a board of a motor with a magnet fixed thereon, wherein said rectangular magnetic resistance sensor chip can be fixed onto the front side of the printed circuit board, and mounted on the board.

In accordance with another aspect of the present invention, there is provided a fixture for a magnetic resistance sensor chip, comprising: a rectangular magnetic resistance sensor chip having a sensing part 20 on one side thereof and an electrode at every corner on both sides thereof; a printed circuit board having a pattern part on its front side, a through-hole coated with a conductor, and a terminal part on its back side, said conductor being connected to the pattern part on the front side and to the terminal part on the back side; a board of a motor; and a magnet mounted onto the board, wherein said rectangular magnetic resistance sensor chip is fixed onto the front side of the printed circuit board in such a way to bring said electrode into direct contact with said pattern part, and the printed circuit board is mounted onto the board of the motor by soldering the back side terminal part onto the board of the motor in such a way to let said sensing part face the magnet at a predetermined distance therefrom.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a schematic side view showing a conventional MR sensor chip engaged to a chip holder;

FIG. 2 is a schematic side view showing a conventional fixture with an MR sensor chip fixed thereto;

FIG. 3 is a schematic perspective view showing a plate type MR sensor chip of the present invention;

FIGS. 4a and 4b are schematic perspective views showing the front and the rear surface of a PCB onto which the MR sensor chip of the present invention is mounted, respectively; and

FIG. 5 is a schematic side view showing a fixture for an MR sensor chip in accordance with the present invention.

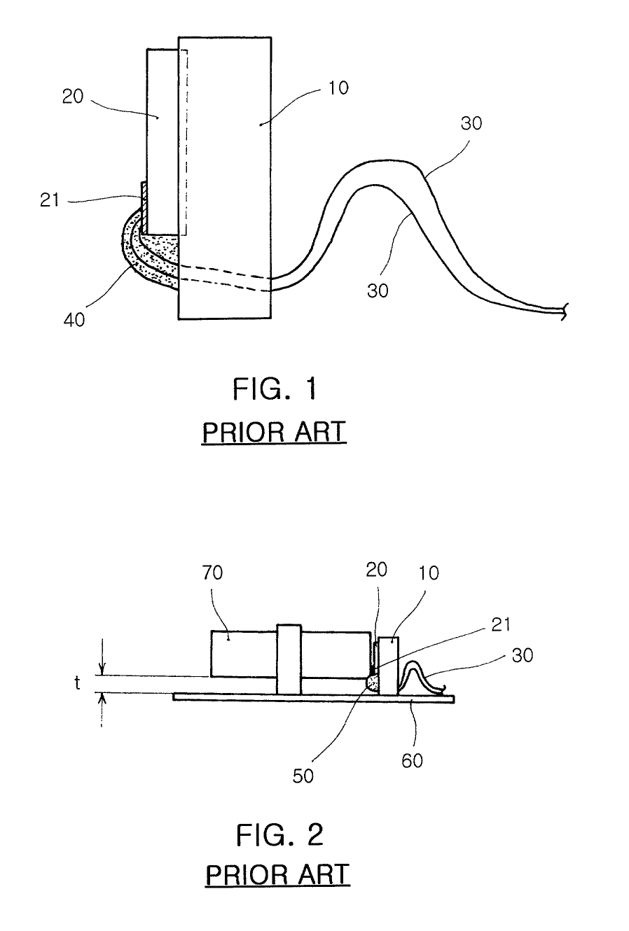

### PREFERRED EMBODIMENTS OF THE INVENTION

The application of the preferred embodiments of the present invention is best understood with reference to the accompanying drawings, wherein like reference numerals are used for like and corresponding parts, respectively.

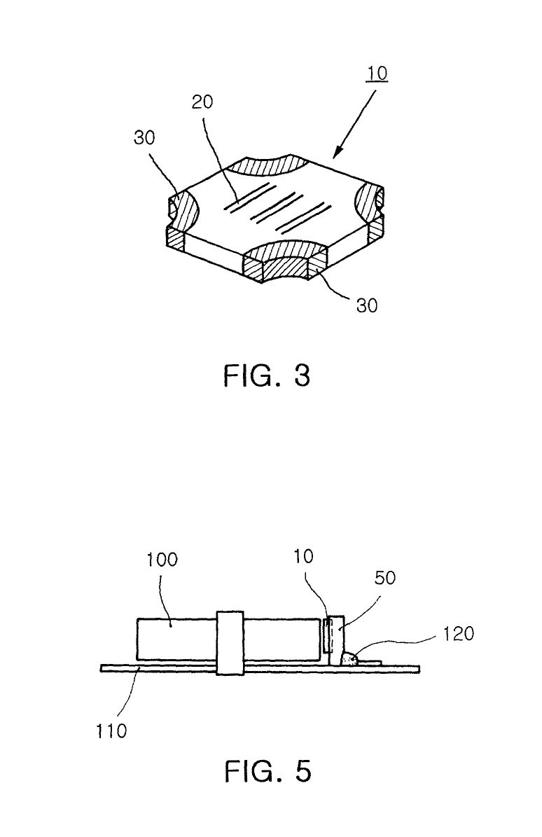

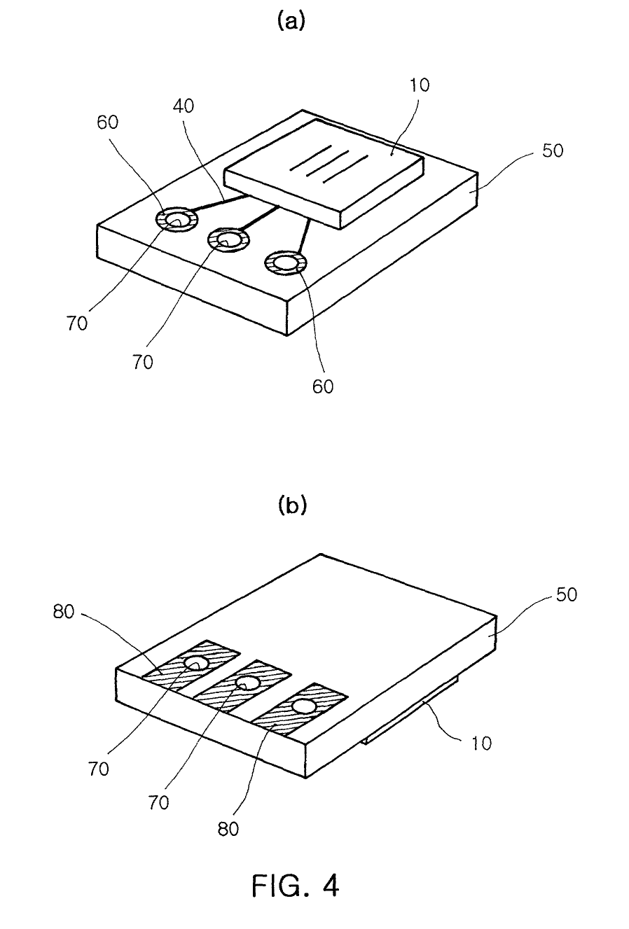

Referring to FIG. 3, there is illustrated an MR sensor chip of the present invention. As shown in this perspective view, the MR sensor chip is rectangular with four concave arc corners around each of which an electrode 30 is printed on both sides of the MR sensor chip With reference to FIG. 4, there is illustrated a PCB 50 onto the front side of which the MR sensor chip 10 is mounted by soldering in such a way that the electrodes 30 of the MR sensor chip 10 are connected to pattern parts 40 established on the PCB 50. In addition to the electrodes 30, the pattern parts 40 are connected to through-holes 70 coated with a conductor 60 in the PCB 50. As seen in FIG. 4b, the through-holes 70 coated with the conductor 60 are also connected to terminal parts 80 formed in areas including the through-holes 70 on the back side of the PCB.

Turning to FIG. 5, there is illustrated a board 110 on which there is mounted a magnet 100, along with the MR sensor chip engaged to the PCB 50 having the back side terminal parts 80 connected to the through-holes 70. Standing upright, the PCB 50 associated with the MR sensor chip 10 is mounted by soldering the back side terminal parts 80 onto the board 110 of the magnet 100. As for the magnet 100 of the motor, it is spaceg from sensing parts 20 of the MR sensor chip 10 at a predetermined distance.

A description will be given of the operation of the MR sensor chip fixed to the fixture of the present invention and its effects, below.

As shown in FIGS. 3 to 5, the MR sensor chip 10 has sensing parts on its one side and can be easily mounted onto the board 110 while being fixed to a chip holder, without requiring additional lead frames.

To this end, first, metal masks are deposited on both sides of the rectangular MR sensor chip and patterned to form electrodes 30 around the concave arc corners of the MR sensor chip.

Next, the MR sensor chip 10 is fixed onto the front side of the PCB 50 by soldering. On the front side of the PCB 50 are printed pattern parts 40 which are connected to the MR sensor chip 10 and to the electrodes 30 printed on the back side of the PCB 50. That is, one end of each of the pattern parts 40, which are in direct contact with the MR sensor chip 10 on the front side, is connected to one through-hole 70 coated with a conductor 60 and thus to the back side terminal part 80 because the back side terminal part 80 is formed in an area where the through-hole 80 coated with the conductor 60 penetrates into the PCB 50.

The PCB 50 with the back side terminal parts 80 connected to the through-holes 70 is mounted onto the board 110 of the magnet 100 such that the back side terminal parts 80 are brought into contact with the board 110.

That is, the PCB 50 fixedly associated with the MR sensor chip 10 is let to stand upright on the board 110 of the magnet by soldering the back side terminal parts 80 to the board 110. At this time, the PCB 50 is located such that the sensing parts 20 of the MR sensor chip 10 faces the magnet 100 of the motor at a predetermined distance.

Spaced from the magnet 100 at a predetermined distance, the MR sensor chip 10 of the PCB 50 standing upright on the board 110 can control the rotational speed of the magnet. Because the solder 120 is on the back side opposite to the sensing parts 20, there occurs no interference between the MR sensor chip 10 and the magnet 100, which thus is not required to be spaced from the board at a distance, unlike conventional MR sensor chips.

In the fixture for a double-sided MR sensor chip of the present invention, as described hereinbefore, the MR sensor chip can be fixed to a PCB without requiring an additional holder and mounted onto a board of a motor with ease. Resulting from the novel structure of the plate type MR sensor chip on both sides of which electrode patterns are formed, elimination of a significant number of steps required for fabricating conventional MR sensor chips as well as for fixing and installing it onto a magnet board is accomplished. For instance, the plate type MR sensor chip does not interfere with the magnet upon being mounted onto the board, so that the magnet can be easily installed without being spaced from the board.

The present invention has been described in an illustrative manner, and it is to be understood that the terminology used is intended to be in the nature of description rather than of limitation. Many modifications and variations of the present invention are possible in light of the above teachings. Therefore, it is to be understood that within the scope of the appended claims, the invention may be practiced otherwise than as specifically described.

What is claimed is:

1. A fixture for a magnetic resistance sensor chip, comprising:
a rectangular magnetic resistance sensor chip having a sensing part on one side thereof and an electrode at every corner on both sides thereof;
a printed circuit board having a pattern part on its front side, a through-hole coated with a conductor, and a terminal part on its back side, said conductor being connected to the pattern part on the front side and to the terminal part on the back side; and
a board of a motor with a magnet fixed thereon,
wherein said rectangular magnetic resistance sensor chip can be fixed onto the front side of the printed circuit board, and mounted on the board.

2. The fixture as set forth in claim 1, wherein the magnetic resistance sensor chip is fixed onto the front side of the printed circuit board by soldering in such a way to connect said electrode to said pattern part.

3. The fixture as set forth in claim 1, wherein the printed circuit board with the magnetic resistance sensor chip fixed thereonto is installed on the board of the motor such that the sensing part formed on the front side of the magnetic resistance sensor chip faces the magnet at a predetermined distance therefrom.

4. The fixture as set forth in claim 1, wherein the printed circuit board is installed on the board of the motor such that the terminal part formed on the back side of the printed circuit board is in contact with the board of the motor.

5. A fixture for a magnetic resistance sensor chip, comprising:
a rectangular magnetic resistance sensor chip having a sensing part on one side thereof and an electrode at every corner on both sides thereof;
a printed circuit board having a pattern part on its front side, a through-hole coated with a conductor, and a terminal part on its back side, said conductor being connected to the pattern part on the front side and to the terminal part on the back side;
a board of a motor; and
a magnet mounted onto the board,
wherein said rectangular magnetic resistance sensor chip is fixed onto the front side of the printed circuit board in such a way to bring said electrode into direct contact with said pattern part, and the printed circuit board is mounted onto the board of the motor by soldering the back side terminal part onto the board of the motor in such a way to let said sensing part face the magnet at a predetermined distance.

6. The fixture as set forth in claim 5, wherein the printed circuit board is mounted onto the board of the motor without occurrence of interference between the magnetic resistance sensor chip and the magnet.
